(19) United States
(12) Patent Application Publication
(10) Pub. No.: US 2007/0090459 A1
(43) Pub. Date: Apr. 26, 2007

(54) Multiple gate printed transistor method and apparatus

(75) Inventors: Jie Zhang, Buffalo Grove, IL (US); Hakeem B. Adewole, Schaumburg, IL (US); Paul W. Brazis, South Elgin, IL (US); Timothy J. Collins, Homer Glen, IL (US); Daniel R. Gamota, Palatine, IL (US); John B. Szczech, Schaumburg, IL (US); Jerzy Wielgus, Mount Prospect, IL (US)

Correspondence Address: FITCH EVEN TABIN AND FLANNERY, 120 SOUTH LA SALLE STREET, SUITE 1600, CHICAGO, IL, 60603-3406, US

(73) Assignee: Motorola, Inc.

(21) Appl. No.: 11/259,492

(22) Filed: Oct. 26, 2005

(51) Int. Cl. H01L 27/12

(52) U.S. Cl. 257/350

(57) ABSTRACT

A printed transistor has a first gate (202) printed and disposed on a first side of a printed deposit of semiconductor material (201) and a second printed gate (301) disposed on an opposite side of the printed deposit of semiconductor material. By one approach these elements are provided using a serial printing process. By another approach these elements are provided through use of a lamination process.

### TECHNICAL FIELD

This invention relates generally to semiconductor devices and more particularly to semiconductor devices that have at least one printed device element.

### BACKGROUND

Methods and apparatus that use such techniques as vacuum deposition to form semiconductor-based devices of various kinds are well known. Such techniques serve well for many purposes and can achieve high reliability, small size, and relative economy when applied in high volume settings. Recently, other techniques are being explored to yield semiconductor-based devices. For example, organic, inorganic, and organic/inorganic hybrid semiconductor materials of n- or p-type can be provided as a functional ink and used in conjunction with various printing techniques to yield printed semiconductor devices.

Printed semiconductor devices, however, yield considerably different end results and make use of considerably different fabrication techniques than those skilled in the art of semiconductor manufacture are prone to expect. For example, printed semiconductor devices tend to be considerably larger than typical semiconductor devices that are fabricated using more traditional techniques. As other examples, both the materials employed and the deposition techniques utilized are also well outside the norm of prior art expectations.

Due in part to such differences, in many cases existing materials and techniques are not suitable for use and deployment with respect to printed semiconductor devices. Further, in many cases, semiconductor device printing gives rise to challenges and difficulties that are without parallel in prior art practice. As one example, the performance of printed transistors tends to be limited, at least in part, by such factors as the available number and performance of solution-processable semiconductor inks, available and/or viable printing dimensions and resolution limits, and the environmental sensitivity of printed transistors, to name but a few. As a more specific example, printed feature resolution of traditional graphic art printing is typically limited to tens of microns. Such a limit is not sufficient in all cases for application settings that require higher performance transistors. Improving transistor performance via improved printing resolution, however, represents a considerable (and likely expensive) challenge.

### BRIEF DESCRIPTION OF THE DRAWINGS

The above needs are at least partially met through provision of the multiple gate printed transistor apparatus and method described in the following detailed description, particularly when studied in conjunction with the drawings, wherein:

FIG. 1 comprises a flow diagram as configured in accordance with various embodiments of the invention;

FIG. 2 comprises a side elevational schematic view as configured in accordance with various embodiments of the invention;

FIG. 3 comprises a side elevational schematic view as configured in accordance with various embodiments of the invention;

FIG. 4 comprises a side elevational schematic view as configured in accordance with various embodiments of the invention;

FIG. 5 comprises a side elevational schematic view as configured in accordance with various embodiments of the invention;

FIG. 6 comprises a side elevational schematic view as configured in accordance with various embodiments of the invention; and

FIG. 7 comprises a detail side elevational schematic view as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Generally speaking, pursuant to these various embodiments, one provides a printed transistor having a first gate printed and disposed on a first side of a printed deposit of semiconductor material and a second printed gate disposed on an opposite side of the printed deposit of semiconductor material. By one approach these elements are provided using a serial printing process. By another approach these elements are provided through use of a lamination process.

So configured, this double-gate transistor structure offers enhanced performance. This enhanced performance results, at least in part, by increasing the charge density in the transistor channel region to thereby provide higher ON current while simultaneously reducing OFF current requirements. These teachings are quite compatible with current graphic art printing technologies and presently available materials. If desired, the additional gate can serve a further purpose by substantially shielding the semiconducting material from at least one ambient influence that is detrimental to the semiconducting material. So configured, these teachings can provide the additional benefit of improving the expected longevity of the resultant transistor.

These and other benefits will become more evident to those skilled in the art upon making a thorough review and study of the following detailed description.

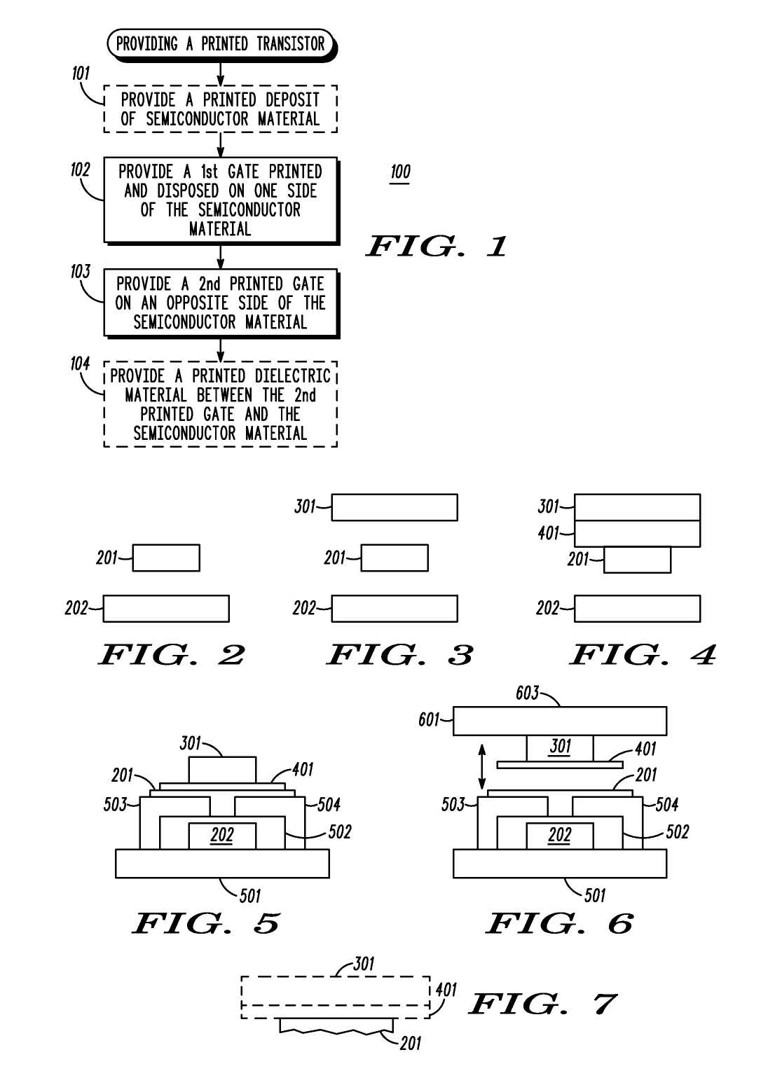

Referring now to the drawings, and in particular to FIG. 1, an overall process for providing a printed transistor 100 representative of these various teachings comprises, in an optional though preferred approach, providing 101 a printed deposit of semiconductor material. This typically comprises use of a printing substrate of choice. The substrate can comprise any suitable material including various rigid and non-rigid materials. In a preferred embodiment, the substrate comprises a flexible substrate comprised, for example, of polyester or paper. The substrate can be comprised of a single substantially amorphous material or can comprise, for example, a composite of differentiated materials (for example, a laminate construct). In a typical embodiment the substrate will comprise an electrical insulator though for some applications, designs, or purposes it may be desirable to utilize a material (or materials) that tend towards greater electrical conductivity.

This process 100 then provides for provision 102 of a first gate printed and disposed on one side of the printed deposit of semiconductor material. To generally illustrate this point, and referring momentarily to FIG. 2, a printed deposit of semiconductor material 201 has a first gate 202 printed and disposed on one side thereof. These elements may be physically adjacent one another or, more likely, will be spaced apart from one another as suggested by the illustration in order to accommodate intervening layers of choice.

Referring again to FIG. 1, this process 100 also provides for provision 103 of a second printed gate on a side of the printed deposit of semiconductor material that is opposite to the side mentioned above. To generally illustrate this point, and referring now momentarily to FIG. 3, a second gate 301 is disposed on a side of the semiconductor material 201 that is opposite the side having the first gate 202. This second gate 301 may be comprised of a same material as the first gate 202 or may be comprised of a different material depending upon the needs and requirements of a given application setting. In general, of course, both gates 202 and 301 will likely be comprised of electrically conductive material.

Referring again to FIG. 1, in an optional though preferred step this process 100 further provides for provision 104 of a printed dielectric material disposed between the second printed gate and the deposit of semiconductor material. To again generally illustrate this point, and referring now momentarily to FIG. 4, such a printed dielectric layer 401 is depicted as being disposed between the semiconductor material 201 and the aforementioned second gate 301.

The above-described device elements are preferably, though not necessarily, comprised of one or more inks including, for example, inks that comprise semiconductor material. Those skilled in the printing arts are familiar with both graphic inks and so-called functional inks, wherein “ink” is generally understood to comprise a suspension, solution, or dispersant that is presented as a liquid, paste, or powder (such as a toner powder). These functional inks are further comprised of metallic, organic, or inorganic materials having any of a variety of shapes (spherical, flakes, fibers, tubes) and sizes ranging, for example, from micron to nanometer. Functional inks find application, for example, in the manufacture of some membrane keypads. Though graphic inks can be employed as appropriate in combination with this process, these inks are more likely, in a preferred embodiment, to comprise a functional ink.

In a preferred approach, such inks are placed on the substrate by use of a corresponding printing technique. Those familiar with traditional semiconductor fabrication techniques such as vacuum deposition will know that the word “printing” is sometimes used loosely in those arts to refer to such techniques. As used herein, however, the word “printing” is used in a more mainstream and traditional sense and does not include such techniques as vacuum deposition that involve, for example, a state change of the transferred medium in order to effect the desired material placement. Accordingly, “printing” will be understood to include such techniques as screen printing, offset printing, gravure printing, xerographic printing, flexography printing, inkjetting, microdispensing, spraying, stamping, and the like. It will be understood that these teachings are compatible with the use of a plurality of such printing techniques during fabrication of a given element such as a semiconductor device. For example, it may be desirable to print a first device element (or portion of a device element) using a first ink and a first printing process and a second, different ink using a second, different print process for a different device element (or portion of the first device element).

For purposes of illustration and not by way of limitation, a transistor can be formed pursuant to these teachings using such materials and processes as follows. With reference to FIG. 5, a first gate 202 as described above can be printed on a substrate 501 of choice using a conductive ink of choice (such as but not limited to a functional ink containing copper or silver, such as DuPont's Ag 5028 combined with 2% 3610 thinner). Pursuant to one approach, air is blown over the printed surface after a delay of, for example, four seconds. An appropriate solvent can then be used to further form, define, or otherwise remove excess material from the substrate. Thermal curing at around 120 degrees Centigrade for 30 minutes can then be employed to assure that the printed gate 202 will suitably adhere to the substrate 501.

A dielectric layer 502 may then be printed over at least a substantial portion of the above-mentioned gate 202 using, for example, an appropriate epoxy-based functional ink (such as, for example, DuPont's 5018A ultraviolet curable material). By one approach, the dielectric layer 502 comprises a laminate of two or more layers. When so fabricated, each layer can be cured under an ultraviolet lamp before applying a next layer.

Additional electrodes 503 and 504 are then again printed and cured using, for example, a copper, nickel, or silver-based electrically conductive functional ink (such as, for example, DuPont's Ag 5028 with 2% 3610 thinner). These additional electrodes 503 and 504 can comprise, for example, a source electrode and a drain electrode. A semiconductor material ink, such as but not limited to an organic semiconductor material ink such as various formulations of polythiophene or a polythiophene-family material such as poly(3-hexylthiophene) or an inorganic semiconductor material ink containing SnO₂, SnO, ZnO, Ge, Si, GaAs, InAs, InP, SiC, CdSe, and various forms of carbon (including carbon nanotubes), is then printed to provide an area of semiconductor material 201 that bridges a gap between the source electrode and the drain electrode.

The above described elements are sufficient to form an operable printed transistor. This serial printing process of applying multiple printed layers can be continued in similar fashion as just described to further apply a second dielectric layer 401 and the aforementioned second gate 301. By one approach the second gate 301 is coupled electrically in common with the first gate. By another approach the second gate 301 is electrically isolated from the first gate such that different biases can be applied to each. The particular approach used will likely depend upon the specific needs and requirements of a given application. In either case the second gate 301 is preferably positioned substantially opposite the first gate 202 such that the transistor channel between the source electrode and the drain electrode is disposed therebetween.

So configured, the inclusion of this second gate serves to increase the charge density in the channel region. This increase may comprise, for example, a doubling of the otherwise resultant charge density. This, in turn, provides a higher ON current for this transistor while also tending to reduce the corresponding OFF current. As a result, a higher performance transistor can be provided with no particular improvement with respect to the enabling printing technologies being otherwise available.

It would also be possible to employ these teachings by combining separate structures as a laminated result. To illustrate, and referring now to FIG. 6, a first transistor 602 as described above can be joined to and laminated with a second structure 603 that comprises a substrate 601 having the second gate 301 and corresponding dielectric layer 401 printed thereon. These two structures can be permanently joined to one another using, for example, a suitable adhesive of choice. Other approaches to achieving such joinder may also be available for use in a given application setting.

When providing the second gate as described herein, it may also be desirable (at least in some application settings) to provide the second gate such that the second gate and second dielectric substantially shields the semiconducting material from at least one ambient influence that is detrimental to the semiconducting material. For example, many semiconducting materials considered useful in this context are sensitive to exposure to such ambient influences as one or more of oxygen, light (such as ultraviolet light), contamination (such as but not limited to organic material such as dirt, oils, and so forth), moisture, and the like. The second gate can serve to shield the semiconductor material from such influences provided the second gate layer adequately covers the semiconductor material area(s) of concern and provided further that the second gate is comprised of a material (or materials) having the desired barrier-like properties as is otherwise understood in the art. Such an arrangement is generally depicted in the illustration provided at FIG. 7 where the second gate 301 has sufficient expanse to provide such a shield for the semiconductor material 201.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept.

1. A transistor comprising:
a printed layer of semiconducting material;
a first printed gate disposed on a first side of the printed layer of semiconducting material;
a second printed gate disposed on a second side of the printed layer of semiconducting material, which second side is opposite the first side.

2. The transistor of claim 1 wherein the printed layer of semiconducting material, the first printed gate, and the second printed gate comprise printed layers of a serial printing process.

3. The transistor of claim 1 wherein the second printed gate comprises a first structure that has been laminated onto a second structure that comprises the printed layer of semiconducting material and the first printed gate.

4. The transistor of claim 1 wherein the first printed gate and the second printed gate are comprised of a substantially similar material.

5. The transistor of claim 1 wherein the first printed gate and the second printed gate are comprised of substantially dissimilar materials.

6. The transistor of claim 1 wherein the second printed gate is disposed and configured to shield the printed layer of semiconducting material from at least one ambient influence that is detrimental to the semiconducting material.

7. The transistor of claim 1 further comprising a dielectric material disposed between the second printed gate and the printed layer of semiconducting material, wherein the dielectric material substantially shields the semiconducting material from at least one ambient influence that is detrimental to the semiconducting material.

8. The transistor of claim 1 wherein the second printed gate substantially shields the semiconducting material from at least one ambient influence that is detrimental to the semiconducting material.

9. The transistor of claim 8 wherein the ambient influence comprises at least one of oxygen, light, contamination, and moisture.

10. The transistor of claim 9 wherein the ambient influences comprise at least both of oxygen and moisture.

11. A process comprising:
providing a printed transistor having:
a first gate printed and disposed on one side of a printed deposit of semiconductor material;
a second printed gate on a side of the printed deposit of semiconductor material that is opposite to the one side.

12. The process of claim 11 wherein providing a second printed gate comprises printing the second printed gate on a side of the printed deposit of semiconductor material that is opposite to the one side.

13. The process of claim 11 wherein providing a second printed gate comprises:
providing a substrate;
printing the second printed gate on the substrate to provide a second gate structure;
laminating the second gate structure to the printed transistor.

14. The process of claim 11 wherein the first gate and the second printed gate are comprised of substantially similar material.

15. The process of claim 11 wherein the first gate and the second printed gate are comprised of substantially dissimilar materials.

16. The process of claim 11 wherein providing a printed transistor comprises providing a printed transistor using at least one of:
a contact printing process;
a non-contact printing process.

17. The process of claim 11 further comprising:
providing a printed dielectric material between the second printed gate and the deposit of semiconductor material.

18. The process of claim 11 wherein providing a printed dielectric material between the second printed gate and the deposit of semiconductor material comprises covering the deposit of semiconductor material to thereby seal the deposit of semiconductor material from at least one ambient condition that is detrimental to the deposit of semiconductor material.

19. The process of claim 17 wherein providing a second printed gate comprises providing a second printed gate that covers the deposit of semiconductor material to thereby seal the deposit of semiconductor material from at least one ambient condition that is detrimental to the deposit of semiconductor material.

20. The process of claim 19 wherein the at least one ambient condition comprises at least one of oxygen, light, contamination, and moisture.
